(19) United States
(12) Patent Application Publication
(10) Pub. No.: US 2003/0207099 A1
(43) Pub. Date: Nov. 6, 2003

(54) Low-contact-angle polymer membranes and method for fabricating micro-bioarrays

(76) Inventors: Susan D. Gillmor, Madison, WI (US); Ferencz S. Denes, Madison, WI (US); Max G. Lagally, Madison, WI (US)

Correspondence Address: BOYLE FREDRICKSON NEWHOLM STEIN & GRATZ, S.C., 250 E. WISCONSIN AVENUE, SUITE 1030, MILWAUKEE, WI, 53202, US

(21) Appl. No.: 10/136,181

(22) Filed: May 1, 2002

(51) Int. Cl. C23C 16/50; B32B 3/24

(52) U.S. Cl. 428/304.4; 427/535; 427/536; 427/255.39

(57) ABSTRACT

A membrane having a stable low-contact angle that is used as a template in forming biological microarrays is provided. The membrane is formed of a polymeric material that has been surface modified by a first plasma treatment and subsequently by a second plasma treatment. The surface modification accomplished by the first plasma treatment results in a significant reduction in the contact angle for the membrane, causing the membrane to become hydrophilic, and the surface modification by the second membrane treatment permanently stabilizes the reduction in the contact angle produced by the first plasma treatment. The resulting membrane allows a solution containing a biological material to wet the surface of the membrane such that the membrane can quickly and easily form a biological microarray on substrate in which the features of the array are distinctly formed on the substrate.

### FIELD OF THE INVENTION

The present invention relates to membranes for use as templates in forming biological microarrays, and more specifically to a membrane that has been subjected to surface modification with two separate plasma treatments to produce a membrane with a permanently reduced contact angle.

### BACKGROUND OF THE INVENTION

In the past decade, both academic laboratories and the biotechnology industry have created a flourishing group of DNA-array makers, with applications in high-throughput analyses for gene expression, gene variation, toxicology, and drug development, to name a few. These efforts have led to the development of several different strategies for DNA attachment at feature sites on a substrate to form the array on the surface on the substrate. Some laboratories use in situ synthesis on the surface to create the different DNA strands one base at a time. Others use an ex situ approach in which they completely synthesize the entire strand before attaching it to the surface. Both methods have advantages and pitfalls, and neither is ideal. In both synthesis modes, glass, silicon, and plastic have emerged as preferred choices for the substrates to which the DNA strands are attached.

The in situ approach, in which one base at a time is added to the feature site on the surface of the substrate via a cyclical surface chemistry scheme in a known manner, works at present only for DNA and small peptide chains, and thus is quite limited, despite the fact that the feature size in the array can be small and many different DNA strands can be processed in parallel.

The ex situ approach has a straightforward strategy, namely, to synthesize the DNA strand completely and then to place small droplets of solution containing the DNA strand on a substrate surface that has already been prepared for the reception or attachment of the DNA. If the droplet volume is small enough and the spacing is large enough, then an array of DNA spots is easily created on the substrate surface. A similar approach for synthesizing an array can be taken with respect to proteins and other biological species of interest. For example, proteins can be synthesized, purified and allowed to fold into their correct 3-D configuration and then placed on a substrate surface in order to form an array.

However, in this method the substrate surface is uniform and the array sites are undefined on the surface. Thus, a common problem for this method is that the DNA droplets placed on the array surface bleed into each other. As a result, with current loading technology, the minimum spacing that can be achieved by this method is ˜200 μm between droplets of the DNA solution.

The process of chemically patterning the substrate surface has overcome the limitations described with respect to the ex situ array synthesis procedures when complete strands of DNA or other molecules are attached to the surface to create the array. The chemically patterned substrate surface has an inert background, and a number of reactive array sites chemically created on the substrate surface. In performing the ex situ method with a chemically patterned surface, aqueous solutions of DNA are placed onto the reactive sites and the droplets of the solution become pinned at those sites on the array element due to the attractive or bonding interaction between the reaction sites and the solution. Also, a repelling interaction between the aqueous DNA solution and the background between the reactive sites prevents the droplets from spreading across the substrate surface, negating any molecular attachment between the elements of the array by acting as a barrier for diffusion of the droplets between the array sites. Combined with a covalent-bonding attachment scheme for completely synthesized and purified DNA strands, high-purity arrays with high positional fidelity, excellent stability, small feature size, and minimal cross talk between features can be fabricated. With a chemically patterned surface, the array features or sites can be considerably smaller, for example, 20 μm in diameter or less. The density of array sites can then be equal to that capable in a base-by-base attachment scheme and, because pure pre-synthesized strands are attached, the reliability of the array sites is greater than that found in base-by-base fabricated arrays. In addition, the total information density of the array can be higher than arrays fabricated by the in situ method.

In previous work, a chemical patterning technique has been developed for use with the ex situ method incorporating gold and alkane-thiol chemistry via UV photopatterning. The array sites formed on the substrate are hydrophilic, and the substrate background is hydrophobic between the sites. The difference in wetting properties of the various parts of the surface allows aqueous DNA solutions to be pinned at the specific array sites and securely bound to the substrate surface for high purity and long base sequences with minimal surface contamination. However, the major limitation of this type of process is that chemical patterning relies on the development of specific surface chemistries that must be tailored to each particular attachment system. Thus, though the chemically patterned surface provides a well-defined array, the development of the surface chemistry for the array is a highly time and work intensive process.

As an alternative to the previous methods, the use of a template that is positionable over a substrate surface to confine solutions to those array sites defined by the template would make possible the formation of high-density arrays on multiple non-chemically patterned surfaces. The use of these types of templates has been explored with the use of various polymer membranes, such as polydimethyl siloxane (PDMS), as the templates. The PDMS is formed into a film with holes or apertures extending through the film in a preselected array pattern. The film is then placed over a substrate surface, thereby creating a watertight seal with the substrate surface and capable of producing a patterned array on the surface without the need for a chemical patterning methodology. More specifically, when a substrate surface that has a membrane positioned on it is exposed to an aqueous solution by placing droplets of the solution on the membrane, the molecules in the solution attach only to the specific regions of the surface exposed by the holes in the membrane.

However, the high hydrophobicity of PDMS membranes becomes an obstacle when loading aqueous solutions into very small features or holes in the membrane. The aqueous solution is rejected by the hydrophobic membrane even though the array elements (i.e. the exposed parts of the surface) are hydrophilic. As shown in FIGS. 1a and 1b, when an aqueous DNA solution is loaded onto a substrate covered with a hydrophobic membrane template, the solution interacts imperfectly with the surface of the membrane resulting in ring-like features on the array.

As a result, it is desirable to develop a method for fabricating a membrane suitable for use as a template in forming a biological microarray in which the contact angle, i.e., the hydrophobicity of the membrane, is sufficiently reduced to enable aqueous solutions to fill openings formed in the membrane and contact the underlying hydrophilic substrate surface in order to form the microarray.

### SUMMARY OF THE INVENTION

It is an object of the present invention to provide a membrane suitable for use as a template in forming a biological microarray that has a stable, reduced contact angle illustrating an increased hydrophilic characteristic for the membrane.

It is another object of the present invention to provide a method for altering or modifying the surface of the membrane in order to form a membrane with a stable, reduced contact angle.

It is still another object of the present invention to provide a method for forming a membrane having a stable, reduced contact angle that allows the membranes to be easily and quickly reproduced in large numbers.

The present invention is a membrane and method for forming a membrane used as a template in forming a biological microarray which has a stable, reduced contact angle, such that the membrane readily enables an aqueous solution containing a biological material to enter openings in the membrane and contact and attach to exposed portions of a substrate surface on which the membrane is positioned. The membrane is typically formed of a polymer material using any of the standard membrane fabrication procedures known in the art. The polymer membrane formed pursuant to one of these procedures normally has a high contact angle, such that the membrane is generally hydrophobic in nature. After formation, the membrane is processed to modify the surface of the membrane by using two consecutive plasma treatments, which significantly and permanently reduce the contact angle of the membrane such that the resulting membrane has a lower contact angle and hence the solutions can wet the membrane. The membrane can then be placed onto a hydrophilic substrate and used to form a biological microarray in which an aqueous solution containing DNA or another biological material that is applied to the surface of the membrane wets the surface of the membrane and enters the holes or apertures originally formed in the membrane. Thus, when the membrane is removed from the substrate, the DNA solution is effectively attached and precisely positioned on the hydrophilic substrate to form the microarray.

Additional embodiments and characteristics of the present invention will be made apparent from the following detailed description taken together with the drawings.

### BRIEF DESCRIPTION OF THE DRAWINGS

The drawings illustrate the best mode currently contemplated of practicing the present invention.

In the drawings:

FIGS. 1a-1b are photographs illustrating biological microarrays formed with unmodified membrane templates;

FIG. 2 is a schematic view of a method of forming a membrane template to be treated in the method of the present invention and the placement of the membrane on a hydrophilic array substrate;

FIGS. 3a-3b are photographs illustrating the formation of a biological microarray using a surface modified template membrane formed according to the present invention; and

FIG. 4 is a graph illustrating the change over time of the contact angles of membranes treated with oxygen plasma and SiCl₄ plasma.

### DETAILED DESCRIPTION OF THE INVENTION

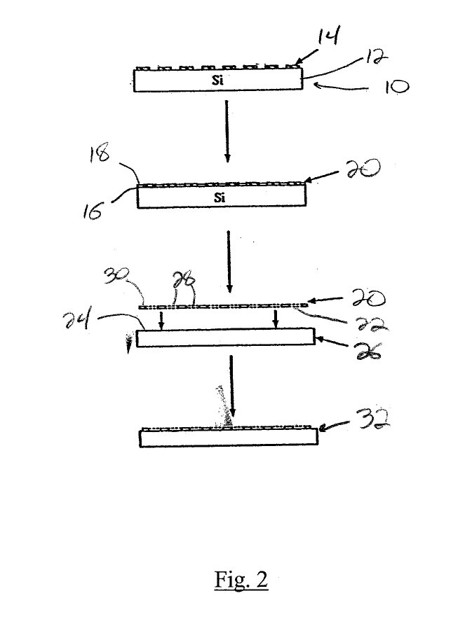

With reference now to the drawing figures in which like reference numerals designate like parts throughout the disclosure, a master utilized in formation of the membranes is indicated generally at 10 in FIG. 2. The master 10 is formed of a silicon substrate 12 including a number of pillars 14 extending upwardly from one side of the silicon substrate 12. The master 10 is created using standard semiconductor etching or microfabrication technology as is known in the art to form the pillars 14 with the desired size and spacing on the substrate 12. The pillars 14 are preferably 20 μm or greater in height and have a length and/or width of between 5 μm and 500 μm. Preferably, the pillars 14 are formed to be with a diameter of approximately less than 20 μm.

After the desired pattern of pillars 14 has been created on the silicon substrate 12, a sacrificial layer of a photoresist 16, such as 1827 Microposit sold by Shipley Co., Inc. of Newton, Mass., is spun onto the master 10 over the substrate 12 and the pillars 14. Afterwards, a mixture 18 of a suitable polymer, such as polydimethylsiloxane (PDMS), sold by Dow Corning of Midland, Mich. under the trade name Sylgard 184, and toluene, obtained from Fisher Scientific of Chicago, Ill., in a 1:1 volume ratio is spun onto the master 10 over the photoresist 16 and allowed to cure at 90° C. for approximately twelve (12) hours to create a cross-linked polymer, which retards bond rotation at the surface about the Si—O—Si backbone. Other siloxane polymers and polymer blends may also be used.

The cured polymer mixture forms a thin lace-like elastomer or membrane 20 having a thickness of between about 5 μm and about 10 μm that can be used as a patterning device or template. When the master 10 supporting the membrane 20 is subsequently placed in an amount of acetone, obtained from Fisher Scientific, the layer of photoresist 16 between the membrane 20 and the silicon substrate 12 and pillars 14 dissolves, separating the membrane 20 from the master 10. Tweezers (not shown) or other suitable implements can then be employed to pull the membrane 20 off of the master 10 and remove the membrane 20 from the acetone bath. The membrane 20 is then placed in a milder environment, such as an ethanol bath and allowed to soak for a suitable amount of time. The membrane 20 is now ready for use.

During the etching process, the pillars 14 form to have a taper at the top. During the curing process, the top, or oven exposed side of the membrane 20 has a slightly higher contact angle than the bottom side which rests next to the master 10. Due to the tapered shape of the master 10 and hence the membrane 20, it is preferable to position the top side of the membrane 20 against a hydrophilic surface 24 of a substrate 26 to form a watertight seal. The smaller end opening of each aperture 28 is therefore positioned next to the surface 24 and the larger end of the aperture 28 interacts with the solution, directing it to the surface 24. Thus, the top side of the membrane 20 is normally used as a lower surface 22 when in use, as shown in FIG. 2, and the bottom side is used as an upper surface 30. However, both sides of the membrane 20 will adequately perform the function of patterning the surface and either surface 22 or 30 can be modified pursuant to the method of the present invention.

To use the membrane 20, the lower surface 22 of the membrane 20 is positioned on a hydrophilic surface 24 of a substrate 26 to form a watertight seal therebetween. In this position, the holes or apertures 28 formed in the membrane 20 will allow any aqueous solution placed onto the upper surface 30 to pass through the apertures 28 and attached to the exposed portions of the hydrophilic surface 24. Then the membrane 20 can be removed, leaving behind only the solution that has attached to the exposed portions of the substrate 26 to form the array 32.

However, as discussed previously, the polymeric membranes 20 formed in this manner, and particularly those membranes formed of PDMS, are generally hydrophobic in nature and have a high contact angle. Thus, any aqueous biological solution applied to the surface of the membrane 20 will tend to bead up on the surface of the membrane 20 instead of wetting the surface and flowing into the apertures 28 formed within the membrane 20 in order to create the microarray on the substrate 26. Therefore, it is desirable to modify the surface of the membrane 20 in order to lower the contact angle of the membrane 20, rendering the membrane 20 more hydrophilic and allowing an aqueous solution to wet the surface of the membrane 20 and form a microarray.

Previous research has been conducted on polymer membranes of this type, i.e., PDMS, by attempting to modify the surface of the membrane using a plasma, which is a state of matter generated when a gas is subjected to energy sufficient to break down the molecular integrity of the gas. This research has demonstrated that when a polymer membrane 20 is exposed to oxygen, nitrogen, helium, or argon plasmas at various pressures, powers, and times, there are two typical results regarding the contact angle of the membrane 20. In one resulting situation, a silica-like layer (not shown) forms on the surface on the polymer membrane 20, which cracks, creating unstable contact angles which vary over the entire surface of the membrane 20. In a second situation, after the plasma treatment, there is an initial change to a lower contact angle for the surface of the membrane 20 such that loading of the array is initially easier. The reason for this is the formation of SiOH, SiCH₂OH and SiCOOH groups on the surface of the membrane by the oxygen plasma. These groups are polar in nature and interact with the aqueous solution to allow the solution to wet the membrane surface and enter the apertures. However, these oxygen (O₂) treated membranes do not have a “shelf life” and over time, the wettability of the surface of the membrane 20 reverts completely to its original highly hydrophobic nature. This is because of the migration of low-molecular-weight, non-polar polymer chains from within the bulk of the membrane 20 to the surface and the reorientation of the polar surface groups formed on the membrane 20 by the plasma treatment as the membrane ages. Also, because this change or reversion is not uniform, at a given time different regions of the membrane can behave differently with respect to an aqueous solution loaded onto the array.

As a result, it was necessary to develop a procedure to stabilize the reduction of the contact angle of a polymer membrane 20 that has previously been treated by an oxygen, nitrogen, helium or argon plasma to reduce the contact angle of the membrane 20 in order to facilitate the use of the membrane 20 as a template for a biological microarray.

To this end, it has been discovered that, after a pre-treatment or first treatment of a membrane 20 with one of the above-listed plasmas in a known manner, a second, subsequent treatment of the membrane 20 with a second plasma formed from silicon tetrachloride (SiCl₄) gas modifies the polymer surface of the membrane 20 via the SiCl₃⁺ ion, which is highly reactive and adds to the polar group sites formed on the membrane surface by the oxygen plasma treatment. The SiCl₃⁺ cation forms a planar trigonal structure with a 3° distortion from the 120° ideal structure, which is extremely unstable and has been produced only in the gas phase. The instability of the SiCl₃⁺ cation in the SiCl₄ plasma permits surface modification of inert polymer substrates such as the membrane 20. More specifically, in the second plasma treatment, the SiCl₄ gas ionizes in the plasma state and forms the SiCl₃⁺ cation which adds to the SiOH, SiCH₂, and the SiCOOH groups previously formed on the membrane surface by the oxygen plasma. The resulting membrane surface includes large polar groups, such as Si—CH₂—SiCl₃, Si—SiCl₃, SiCOSiCl₃, etc., that are covalently attached to the surface and which are too large to become buried within the membrane either through bond rotation or through the migration of low molecular weight groups from within the bulk of the membrane 20, as occurs when the membrane is treated only with an oxygen plasma. Therefore, the surface of the membrane 20 remains modified to the reduced contact angle configuration, forming a membrane 20 with hydrophilic surface characteristics. These characteristics are defined by the surface of the membrane 20 which now has a mixture of unmodified methyl groups (—CH₃), and chlorine groups (SiCl₃) positioned over the surface of the membrane 20. The surface of the membrane 20 therefore interacts with water differently than an untreated membrane 20 because, while the methyl groups repel an aqueous solution applied to the surface, the chlorine atoms hold a dipole charge through their bond with the central silicon atom and interact with the polar water molecules in the aqueous solution to allow the solution to wet or spread on the surface and interact with the holes or apertures 28 in the membrane 20.

In addition to SiCl₄ gas, a number of other gases that will stabilize the reduced contact angle of the membrane can be used to form the second surface modifying plasma treatment, such as carbon tetrachloride gas (CCl₄). CCl₄ is commonly used to etch aluminum (Al). Contrary to what occurs for SiCl₄, in the plasma state CCl₄ disassociates to form Cl⁻ ions and CCl₃^{·} radicals. These ions and radicals recombine in the plasma to form a number of different species: Cl₂, C₂Cl₄, and chains of (—C₃₋₆Cl—)ₙ. In the aluminum etching process, the Cl^{·} and Cl⁻ act as etchants, while the CₙClₘ products passivate the surface. When CCl₄ is used as the second plasma to modify the surface of the membrane 20, this passivation via the carbon-chloride chains (13 C₃₋₆Cl—)ₙ results in those chains functioning in the same manner as the SiCl₃⁺ ions by attaching to the surface groups formed by the first plasma on the membrane and maintaining the reduced contact angle for the membrane 20.

### EXPERIMENTAL

The plasma processing of the PDMS membranes with oxygen, SiCl₄ and CCl₄ was conducted using more than one system as vacuum chambers are sensitive to reactive gases. For the membranes treated with only the oxygen plasma, the PDMS membranes were exposed to the oxygen plasma in Plasma Therm 74 system at 100 W at 100 mt using a 13.56 MHz power supply for 30 s. In the second procedure, after pre-treating the PDMS samples for 30 s with an oxygen plasma at identical pressures and power settings, we exposed the membranes to the SiCl₄ plasma in the same type of system at 200 W at 200 mt. These PDMS membranes were exposed to the SiCl₄ plasma for 30 s, 2 min and 5 min. In the third procedure, in which CCl₄ is used as the second plasma in the treatment, we exposed the PDMS membranes at 100 W at 4.5 mt to plasma formed of a CCl₄ and O₂ mix (12:1) after pretreating the membranes with oxygen plasma for 30 s at the same pressure and power settings.

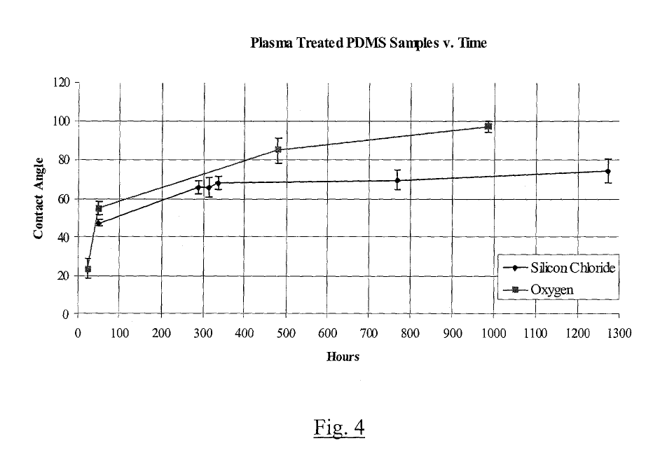

The membranes that were modified pursuant to each of these procedures were then analyzed and compared with each other and with completely untreated membranes. To study the surface modification of both the treated membranes and the untreated membranes, the various membrane samples were examined over time with several instruments. The contact angle data were collected for each membrane sample with a DataPhysics Contact Angle System OCA plus (+) 15. These data determined the change in wetting characteristics resulting from the various plasma treatments and over time, and are shown in Table 1 and FIG. 4. In the roughness studies conducted on the samples utilizing a Digital Instruments Multimode Atomic Force Microscope in tapping mode, the root mean square (RMS) of the surface roughness was determined for each sample to see the change in the surface roughness of each of the sample membranes resulting from the different testing procedures. Also, X-ray photoelectron spectroscopy (XPS) studies were conducted on the sample membranes with a Perkin-Elmer Physical Electronics 5400 Small Area System (Mg source; 15 kV, 300 W; pass energy 89.45 eV; angle 45°). These data are represented in Table 2 and illustrates both the elemental shifts in the surface and the chemical bonding differences of the various samples. Finally, with the attenuated total reflection Fourier transform infrared (ATR-FTIR) spectra collected with a Mattson RS1 system with a Graseby Specac ATR attachment, the chemical groups on the surface of the membranes were determined. These data are represented in Table 3.

TABLE 1
Contact Angle Comparison of PDMS Samples

| | | SiCl₄ Plasma | |
|---|---|---|---|
| | Untreated | 30 s | 2 min, 5 min |
| Initial | 112.9° ± 4.1° | 47.5° ± 1.8° | Cracked |
| Final | 114° ± 3.9° | 74.1° ± 6.3° | Cracked |
| | 1000 hrs | 1250 hrs | |
| | | CCl₄ Plasma | |
| | O₂ Plasma | 30 s | 1 min |
| Initial | 24.8° ± 4.8° | 48.5° ± 9.2° | 39.4° ± 6.5° |
| Final | 97° ± 3.0° | 94.6° ± 1.7° | 87.0° ± 4.8° |
| | 1000 hrs | 1150 hrs | 1150 hrs |

Static contact angles with water are a measure of the hydrophobic/hydrophilic nature of the surface. A contact angle of less than 90° indicates water partially wets the surface. Immediately after plasma treatment (if any), the initial values for the contact angle were recorded. The final value is representative of the contact angle when the PDMS membrane reached a stable plateau and did not exhibit any more significant changes over time.

As shown graphically in FIG. 4, the contact angle of the PDMS membrane samples treated with SiCl₄ plasma and O₂ plasma saturates within the range of error after 350 hrs, while the contact angle of the PDMS membrane samples treated only with O₂ plasma continually increases over time toward the contact angle values for untreated membranes. More specifically, when the sample membranes were exposed to the SiCl₄ plasma, the initial investigations show a permanent contact angle change for a 30 s exposure to 74.1° from its original 112.9°. When the sample membranes that were exposed to the SiCl₄ for longer periods of time were analyzed, the PDMS membranes showed silica-like layers that formed on the membranes, an undesirable characteristic similar to those layers that sometimes occur due to plasma treatment of various types of gas (oxygen, helium, and nitrogen to name a few) of the membrane.

The contact angle measurements shown below also illustrate a permanent wetting or contact angle change, from 112.9° to 94.6° degrees for sample membranes exposed for 30 s to CCl₄ plasma and to 87.0° for samples exposed to the CCl₄ plasma for 1 min., each after a pre-treatment with O₂ plasma.

The surfaces of the samples exposed to the different plasma were imaged, and accurate measurements for the CCl₄ and the untreated samples were collected. The surfaces of the plasma SiCl₄ and the oxygen treated samples mirrored on another in large undulations and significant increases in roughness. There is little change in the surface roughness for the CCl₄ plasma treated membranes compared to the untreated membranes (0.49 nm±0.13 nm untreated and 0.4 nm±0.13 nm CCl₄ treated), indicating that the surface becomes passivated during the CCl₄ plasma treatment process.

TABLE 2
XPS of PDMS Membrane Samples

| | | SiCl₄ Plasma | | |
|---|---|---|---|---|
| | Untreated | 30 s | 2 min | 5 min |
| C | 1.84 | 0.89 | 0.68 | 0.54 |
| Si | 1.00 | 1.00 | 1.00 | 1.00 |
| O | 1.45 | 2.35 | 2.50 | 2.41 |
| Cl | 0.00 | 0.00 | 0.00 | 0.03 |
| | | CCl₄ Plasma | | |
| | O₂ Plasma | 30 s | 1 min | |
| C | 1.36 | 1.36 | 1.18 | |
| Si | 1.00 | 1.00 | 1.00 | |
| O | 2.22 | 2.22 | 2.56 | |
| Cl | 0.16 | 0.16 | 0.10 | |

The above XPS measurements illustrate the surface composition of the various PDMS membrane samples and changes to those surface compositions due to the various plasma treatments. The values are peak heights relative to Si, and the trends in the surface composition caused by the plasma treatments was determined by comparison with an untreated membrane sample.

The XPS analysis data clearly indicate the development of the silica-like layer, with a marked increase in the silicon and oxygen peaks relative to the carbon peaks, for samples exposed to the second SiCl₄, plasma for longer than 30 s. The chlorine peak becomes detectable when the plasma exposure time reaches 5 min. From these data, it appears that a passivation process is occurring with the PDMS membrane samples when treated with the SiCl₄ plasma. Also, the XPS results for the membrane samples exposed for 30 s to the CCl₄ plasma show an increase in carbon to silicon ratio compared with the untreated PDMS membranes, and we see a strong Cl peak, indicating that Cl has become attached to the surface of the membrane. Samples exposed to the CCl₄ plasma for 1 min show a lesser increase in the C and Cl peaks, indicating the beginning of the silica-like layer formation.

TABLE 3
ATR-FTIR Comparison of PDMS Samples

| ART-FTIR | Untreated | SiCl₄ (30 s) | CCl₄ (30 s) | 0₂ |
|---|---|---|---|---|
| (cm⁻¹) | 702 (vw) | 707 (w) | 704 (w) | 702 (w) |
| Surface | 763 (sh) | 763 (sh) | 763 (sh) | 763 (sh) |
| | 791 (s) | 787 (s) | 788 (s) | 789 (s) |
| | 846 (sh) | 847 (sh) | 845 (sh) | 847 (sh) |
| | 926 (vw) | 923 (w) | 914 (w) | 916 (w) |
| | 1013 (s) | 1014 (s) | 1014 (s) | 1010 (s) |
| | 1079 (sh) | 1076 (sh) | 1068 (sh) | 1074 (sh) |
| Surface | | 1193.7 (w) | 1193.7 (w) | 1195.7 (vw) |
| Surface | 1259 | 1259 | 1257 | 1257 |
| | 1417 (w) | 1419 | 1404 | 1419 |
| | 1471 (vw) | 1471 (w) | 1456 (w) | 1465 (w) |
| | 2375 (w) | 2373 (w) | 2362 (w) | 2372 (w) |
| | 2967 | 2966 | 2964 | 2966 |

The above table of ATR-FTIR peaks shows the comparison between membrane samples subjected to the different plasma treatments. The peaks specific to the membrane surface are indicated when compared to a bulk membrane sample. The abbreviations for the peak strength are as follows: sh=shoulder, s=strong, w=weak, vw=very weak. The ATR-FTIR data show characteristic peaks that confirm the surface modification, and the regular bulk peaks, showing that only the surface is affected via the plasma treatment, and not the bulk PDMS forming the plasma treated membranes.

In testing the efficiency of the plasma treated membranes formed pursuant to the SiCl₄ and CCl₄ plasma treatments, a number of microarrays including a glass substrate and both treated and untreated membranes were formed using an aqueous solution containing salmon sperm DNA sold under the trade name Gibco BRL by Life Technologies Inc, Gaithersburg, Md., at concentrations of 100 mg/mL-500 mg/mL DNA in distilled water was sonicated 5 min prior to use with the arrays. The solution was stored at −20° C. when not in use. Droplets of the aqueous DNA solution were then placed on poly-1-lysine coated slides obtained from the Gene Expression Center of Madison, Wis., with various plasma-treated and untreated PDMS membranes disposed on the coated surface of the slide. The DNA solution was allowed to react with the membrane and the poly-1-lysine surface for approximately eighteen (18) hours in a humid environment. The slide was then soaked in a solution of 70% by volume distilled water, 30% absolute ethanol for one (1) hour prior to staining the slide with Molecular Probes Sytox nucleic acid stain (488 nm excitation/520 nm emission) solution of 5 μM distilled water and ethanol (1:1 volume ratio) for thirty (30) minutes to one (1) hour. After staining, the slides were then soaked in 70/30 water/ethanol for thirty (30) minutes to one (1) hour prior to scanning with a Scan Array 5000 Confocal Microscope Scanner at 488 nm with an argon laser.

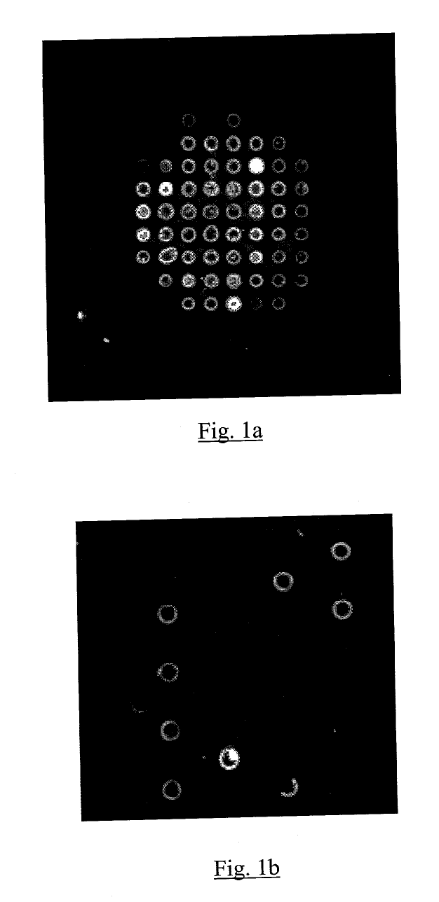

Upon viewing the stained slides, the slides using the PDMS membranes that were plasma treated showed a marked difference from those slides using untreated membranes as templates for DNA microarrays. First, the DNA solution was difficult to load into the array elements on the membrane, even at fifty (50) micron aperture sizes, when non-plasma treated PDMS membranes were used. Second, the arrays that were formed with the non-plasma treated membranes display uneven, ring-like features, as seen in FIGS. 1a and 1b.

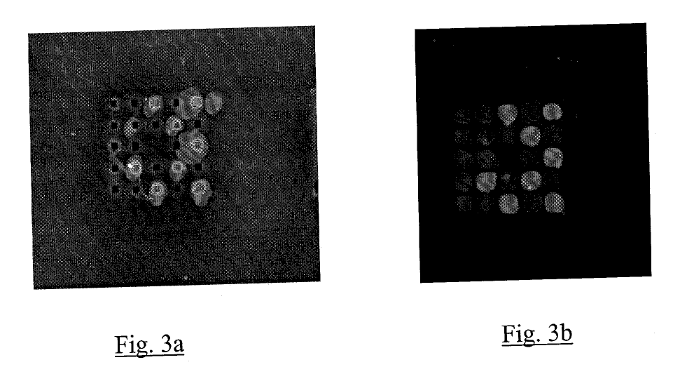

In contrast, FIG. 3a shows the loading of an array that used a template formed of a PDMS membrane treated with a mixture of O₂ and CCl₄ gases in a plasma treatment. As shown in FIG. 3b, even with nonuniform loading, the individual array features remaining on the substrate upon removal of the treated membrane are uniform on the slide surface. Further, depending upon the particular array to be formed using the treated membrane, the process in which the surface of the membrane is modified can be altered by varying the conditions, time of exposure to the plasma, or other parameters of the process in order to “tune” the contact angle of the membrane to be more applicable to the use in forming the desired array.

As the feature sizes used in microarrays decrease, the ability to control the membrane contact angles becomes more important in order to ensure proper formation of the array. The manipulation of the interaction between polymer devices and aqueous solutions in order to form various devices, such as a stencil for DNA microarrays, has numerous possible applications. As PDMS and other polymers become more important and common in the biochip arena and as these devises shrink, the ability to manipulate the wetting properties of the materials becomes a key factor.

Various alternatives are contemplated as being within the scope of the following claims particularly pointing out and distinctly claiming the subject matter regarded as the invention.

We hereby claim:

1. A method for forming a membrane for use in forming a biological microarray, the method comprising the steps of:
a) providing a membrane formed of a polymer and including a number of apertures extending through the membrane between a pair of opposed membrane surfaces;
b) treating at least one of the membrane surfaces with a first plasma; and
c) treating the at least one of the membrane surfaces with a second plasma.

2. The method of claim 1 wherein the polymer forming the membrane is polydimethyl siloxane.

3. The method of claim 1 wherein the first plasma is formed from a gas selected from the group consisting of: oxygen, nitrogen, helium and argon.

4. The method of claim 3 wherein the first plasma is formed from oxygen gas.

5. The method of claim 1 wherein a second plasma is formed from a gas selected from the group consisting of: silicon tetrachloride or carbon tetrachloride.

6. The method of claim 5 wherein the second plasma is formed from a mixture of carbon tetrachloride gas and oxygen gas.

7. The method of claim 6 wherein the second plasma is formed from a mixture of carbon tetrachloride gas and oxygen gas in a ratio of approximately 12:1.

8. The method of claim 1 wherein the step of providing the membrane comprises the steps of:
a) forming the membrane on a master; and
b) removing the membrane from the master.

9. The method of claim 8 wherein the step of forming the polymer membrane comprises the steps of:
a) providing the master;
b) spinning a photoresist onto the master;
c) spinning the polymer onto the master over the photoresist; and
d) curing the polymer.

10. The method of claim 9 wherein the step of removing the membrane from the master comprises the steps of:
a) placing the master and the membrane into a solvent; and
b) lifting the membrane off of the master.

11. A membrane used as a template in forming a biological microarray on a substrate, the membrane formed from a process comprising the steps of:
a) forming the membrane of a polymer, the membrane including a number of apertures extending between a pair of opposed membrane surfaces;
b) treating at least one of the opposed membrane surfaces with a first plasma; and
c) treating the at least one of the opposed membrane surfaces with a second plasma.

12. The membrane of claim 11 wherein the step of treating the at least one opposed membrane surface with the first plasma comprises the steps of:
a) placing the membrane within a plasma chamber to expose the at least one opposed membrane surface; and
b) contacting the at least one opposed membrane surface with the first plasma, wherein the at least one opposed membrane surface is contacted by the first plasma for less than ten minutes.

13. The membrane of claim 12 wherein the at least one opposed membrane surface is contacted by the first plasma for less than five minutes.

14. The membrane of claim 13 wherein the at least one opposed membrane surface is contacted by the first plasma for between fifteen seconds and five minutes.

15. The membrane of claim 12 wherein the first plasma is formed from a gas selected from the group consisting of: oxygen, nitrogen, helium and argon.

16. The membrane of claim 11 wherein the step of treating the at least one opposed membrane surface with the second plasma comprises the steps of:
a) placing the membrane within a second plasma chamber to expose the at least one opposed membrane surface; and
b) contacting the at least one opposed membrane surface with the second plasma, wherein the at least one opposed membrane surface is contacted by the second plasma for less than ten minutes.

17. The membrane of claim 16 wherein the at least one opposed membrane surface is contacted by the second plasma for less than five minutes.

18. The membrane of claim 17 wherein the at least one opposed membrane surface is contacted by the second plasma for between fifteen seconds and five minutes.

19. The membrane of claim 16 wherein the second plasma is formed from a gas selected from the group consisting of: silicone tetrachloride and carbon tetrachloride.

20. A method for forming a biological microarray comprising the steps of:
a) providing a substrate for the microarray having a hydrophilic surface;
b) forming a membrane from a polymer, the membrane including an unmodified membrane surface, a modified membrane surface and a number of apertures extending between the unmodified and unmodified membrane surfaces, wherein the modified membrane surface is treated to increase the wettability of the modified membrane surface;
c) placing the unmodified surface of the membrane on the hydrophilic surface of the substrate;
d) placing a number of droplets of a biological solution on the modified membrane surface; and
e) removing the membrane from the hydrophilic surface of the substrate.

21. The method of claim 20 wherein the step of forming the membrane comprises the steps of:
a) creating the membrane from a generally hydrophobic polymeric material;
b) treating the surface of the membrane to be modified with a first plasma; and
c) treating the surface of the membrane to be modified with a second plasma.

22. The method of claim 21 wherein the first plasma is formed from a gas selected from the group consisting of: oxygen, nitrogen, helium and argon.

23. The method of claim 22 wherein the first plasma is formed from oxygen gas.

24. The method of claim 21 wherein the second plasma is formed from a gas selected from the group consisting of: silicone tetrachloride and carbon tetrachloride.

25. The method of claim 21 wherein the polymeric material is PDMS.

26. The method of claim 21 wherein the modified membrane surface is treated with the first plasma for less than ten minutes.

27. The method of claim 26 wherein the modified membrane surface is treated with the first plasma for less than five minutes.

28. The method of claim 21 wherein the modified membrane surface is treated with the second plasma for less than ten minutes.

29. The method of claim 28 wherein the modified membrane surface is treated with the second plasma for less than five minutes.
